(19) United States
(12) Patent Application Publication
(10) Pub. No.: US 2022/0139709 A1
(43) Pub. Date: May 5, 2022

(54) CONFINED GALLIUM NITRIDE EPITAXIAL LAYERS

(71) Applicant: International Business Machines Corporation, Armonk, NY (US)

(72) Inventors: Ko-Tao Lee, Yorktown Heights, NY (US); Shawn Xiaofeng Du, Mohegan Lake, NY (US); Ning Li, White Plains, NY (US); Xin Zhang, Chappaqua, NY (US)

(21) Appl. No.: 17/089,915

(22) Filed: Nov. 5, 2020

(51) Int. Cl. H01L 21/02; H01L 21/306; H01L 29/66; H01L 29/20; H01L 29/205; H01L 29/778; C30B 29/40; C30B 29/06; C30B 33/08; C30B 25/18; C30B 23/02

(52) U.S. Cl. CPC H01L 21/02639; H01L 21/02381; H01L 21/02458; H01L 21/0254; H01L 21/30625; H01L 29/66462; C30B 23/025; H01L 29/205; H01L 29/7786; C30B 29/406; C30B 29/06; C30B 33/08; C30B 25/18; H01L 29/2003

(57) ABSTRACT

A method of manufacturing an electronic device is provided. The method includes forming a dielectric layer on a Si-based substrate, etching away portions of the dielectric layer to form a crisscrossing grid pattern of remaining portions of the dielectric layer and to expose the substrate in areas where the dielectric layer is removed, forming GaN-based layers on the substrate in growth areas between sidewalls of the remaining portions of the dielectric layer, and forming a semiconductor device on the GaN-based layers.

### BACKGROUND

The present disclosure relates to fabrication methods and resulting structures for semiconductor devices. More specifically, the present disclosure relates to fabrication methods and resulting structures for GaN epitaxial layers that are grown on silicon substrates. Certain GaN epitaxial layers are grown on, for example, a silicon substrate having a <111> crystal plane. In order to achieve high performance for power and radio frequency (RF) devices, GaN material layers having a low dislocation density are generally preferred, and GaN epitaxial layers are sometimes prone to having a high dislocation density. Bulk films grown on large wafers are also prone to bowing, cracking and other defects due to, for example, a differential in thermal expansion coefficients between different materials of different layers.

### SUMMARY

Embodiments of the present disclosure relate to a method of manufacturing an electronic device. A method of manufacturing an electronic device is provided. The method includes forming a dielectric layer on a Si-based substrate, etching away portions of the dielectric layer to form a crisscrossing grid pattern of remaining portions of the dielectric layer and to expose the substrate in areas where the dielectric layer is removed, forming GaN-based layers on the substrate in growth areas between sidewalls of the remaining portions of the dielectric layer, and forming a semiconductor device on the GaN-based layers.

Other embodiments relate to an electronic device. The electronic device includes a dielectric layer provided on a Si-based substrate, the dielectric layer having a crisscrossing grid pattern, GaN-based layers provided on the substrate and in growth areas between sidewalls of the dielectric layer, and a semiconductor device provided on the GaN-based layer.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a perspective view of a dielectric growth confinement pattern formed on a substrate, at an intermediate stage of a semiconductor fabrication process flow, according to embodiments.

FIG. 2 depicts a cross-sectional view of the semiconductor device of FIG. 1 at an earlier stage of the semiconductor fabrication process flow, according to embodiments.

FIG. 3 depicts a cross-sectional view of the semiconductor device of FIG. 2 after additional fabrication operations, according to embodiments.

FIG. 4 depicts a cross-sectional view of the semiconductor device of FIG. 3 after additional fabrication operations, according to embodiments.

FIG. 5 depicts a cross-sectional view of the semiconductor device of FIG. 4 after additional fabrication operations, according to embodiments.

FIG. 6 depicts a cross-sectional view of the semiconductor device of FIG. 5 after additional fabrication operations, according to embodiments.

FIG. 7 depicts a cross-sectional view of the semiconductor device of FIG. 6 after additional fabrication operations, according to embodiments.

FIG. 8 depicts a cross-sectional view of the semiconductor device of FIG. 7 after additional fabrication operations, according to embodiments.

FIG. 9 depicts a cross-sectional view of the semiconductor device of FIG. 8 after additional fabrication operations, according to embodiments.

FIG. 10 depicts a magnified view of a surface roughness profile for a confined GaN epitaxial layer, according to embodiments.

FIG. 11 depicts performance graphs for an example semiconductor device including a confined GaN epitaxial layer for varying dimensions of the confined GaN epitaxial layer window, according to embodiments.

FIG. 12 depicts a magnified view of the dislocation density profile for a confined GaN epitaxial layer, according to embodiments.

### DETAILED DESCRIPTION

The present disclosure describes an electronic device and methods of manufacturing an electronic device. In particular, certain embodiments include a dielectric layer that is formed on a Si-based substrate. Portions of the dielectric layer are etched away to form a crisscrossing grid pattern of remaining portions of the dielectric layer and to expose the substrate in areas where the dielectric layer is removed. In these open windows where the dielectric layer has been removed, a GaN layer is formed on the substrate and in the growth areas between sidewalls of the remaining portions of the dielectric layer. A semiconductor device is then formed on the GaN layer. The crisscrossing grid-shaped dielectric layer has sidewalls that stop the propagation of dislocation defects in the GaN layer. In addition, by separating the growth of the GaN layer into smaller individual areas (i.e., areas that are separated by the dielectric layer barriers), negative effects associated with thermal and lattice mismatch between the Si substrate and the GaN layer may be reduced.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowcharts and cross-sectional diagrams in the Figures illustrate methods of manufacturing nanosheet field-effect transistor (FET) devices according to various embodiments. In some alternative implementations, the manufacturing steps may occur in a different order that that which is noted in the Figures, and certain additional manufacturing steps may be implemented between the steps noted in the Figures. Moreover, any of the layered structures depicted in the Figures may contain multiple sublayers.

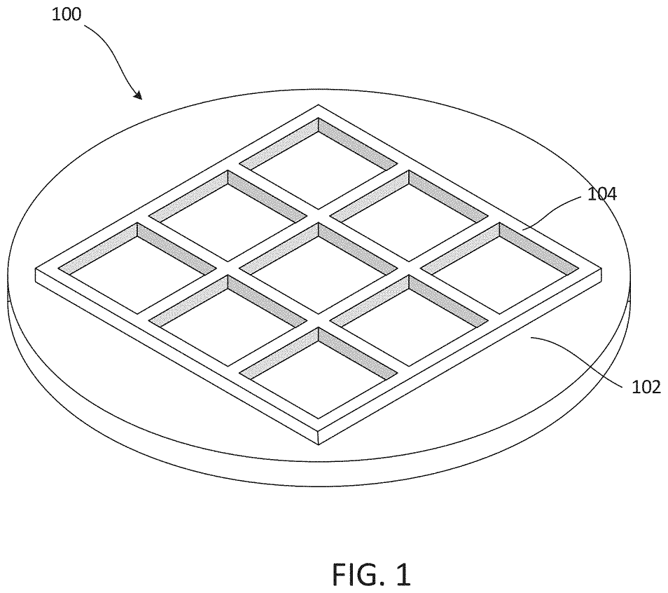

Referring now to the drawings in which like numerals represent the same or similar elements and initially to FIG. 1, a portion of a semiconductor device 100 is shown in perspective view that includes a base substrate 102, and a chess-board shaped (or crisscross shaped) dielectric layer 104 grown on the substrate 102. In certain embodiments, the substrate 102 is a Si substrate having a <111> crystallographic structure and is formed as a flat circular wafer. The wafer may be, for example, 200 mm or 300 mm in diameter, or any other suitable size or shape. As shown in FIG. 1, the dielectric layer 104 is formed in a grid like pattern and includes sidewalls that essentially subdivide the underlying substrate 102 into a plurality of smaller square shaped growth regions upon which a GaN layer or any other suitable layer may thereafter be formed.

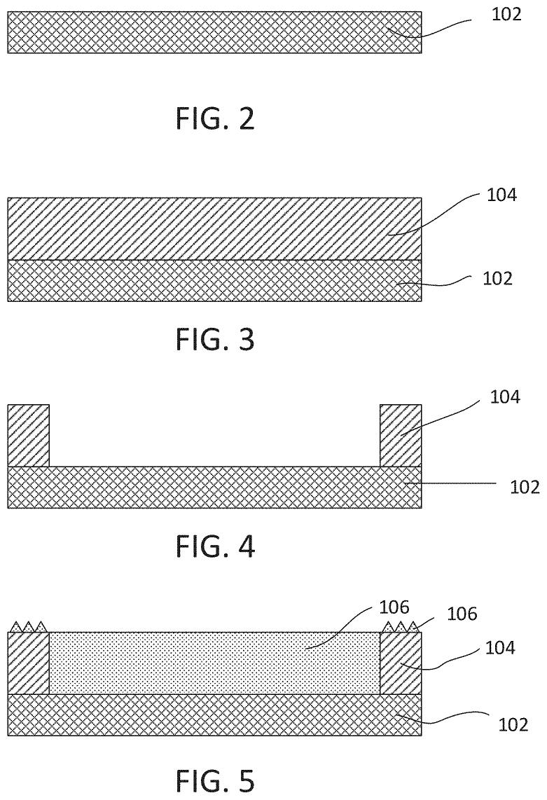

Referring now to FIG. 2, a sideview of the semiconductor device is shown that includes the substrate 102. As mentioned above, in certain examples, the substrate 102 is a Si substrate having a <111> crystal structure. However, it should be appreciated that the substrate may include or be comprised of other materials known in the art.

Referring now to FIG. 3, a dielectric layer 104 is deposited on the substrate 102. For example, the dielectric layer 104 may comprise at least one of PVD, ALD, PECVD, AlOx, TiOₓ, BN, SiN, SiO₂ and SiBCN, or other suitable dielectric materials known in the art. In other examples, the dielectric layer may be a ceramic material, or a composite of several different materials. Initially, the dielectric layer 104 is deposited over the entire surface of the substrate 102. It should be appreciated that although the dielectric layer 104 may be composed of a variety of different materials, it may be desirable that the materials are able to prevent or minimize diffusion and contamination, allow for termination of dislocation defects, and tolerate a high temperature growth process.

Referring now to FIG. 4, etching is performed on the dielectric layer 104 down to the level of the substrate 102, and this etching process exposes certain areas of the substrate. The remaining portions of the dielectric layer 104 form the grid-like or chess-board like structure shown in FIG. 1. Thus, there is a pattern of sidewalls of the dielectric layer that crisscross at 90 degrees to form the grid structure. In general, the dielectric layer 104 pattern can be any suitable shape and have different spacing between the adjacent sidewalls of the crisscrossing portions thereof. The exposed areas of the substrate 102 are areas where the GaN can later be formed. In general, when growing a GaN layer, for example, the GaN can be prone to forming dislocation defects. The sidewalls of the dielectric layer 104 are able to terminate the propagation of these dislocation defects, which may improve the quality of the GaN layer and the performance of the final electronic device. The sidewalls of the dielectric layer 104 essentially subdivide the entire surface of the underlying substrate 102 into a plurality of smaller sized growth regions, and in each of the smaller sized growth regions, the sidewalls of the dielectric layer 104 allow for termination of certain types of growth defects of the subsequently formed layers. The dimensions of the chess-board like structure of the dielectric layer 104 may be varied. For example, the exposed areas of the substrate may be square or rectangular, the spacing between the adjacent sidewalls of the dielectric layer 104 may be varied, and the height and the width of the sidewalls of the dielectric layer 104 may be varied. In certain embodiments, the grid structure of the dielectric layer 104 corresponds to the size of the final semiconductor device, and the area of the substrate 102 covered by the dielectric layer 104 corresponds to areas between adjacent semiconductor devices (i.e., the area where the electronic devices are eventually divided by a sawing or scribe and break process).

The thermal and lattice mismatch between the underlying Si substrate, and the subsequently grown GaN layer can be a major contributor to device performance. For example, the material of the Si substrate may have a different thermal expansion coefficient than the GaN layer. Thus, after the formation of the GaN layer at a high temperature, the device is subsequently cooled. Because of the difference in these thermal expansion coefficients, one of the layers shrinks more than the other during the cooling process, which can cause stress on the wafer. For larger wafers, this thermal stress can also cause the wafer to bow or cup, which can also affect device performance. However, because the grid-like pattern of the dielectric layer 104 has subdivided the wafer into these many smaller GaN growth regions, the surface area of each of the GaN growth areas are much smaller than the original wafer size, which reduces the amount of thermal stress associated with the heating and cooling of the wafers. Thus, in addition to reducing dislocation density of the GaN layers, the sidewall structure of the dielectric layer 104 can also reduce the problems associated with the thermal and lattice mismatch, and thereby increase device performance.

Referring now to FIG. 5, after forming the grid-like structure of the dielectric layer 104, a GaN layer 106 is epitaxially grown over the entire surface of the wafer to fill in the open spaces between the sidewalls of the dielectric layer 104. As shown in FIG. 5, some of the GaN material may also be formed on the upper surfaces of the dielectric layer 104. In certain embodiments, these additional portions of the GaN layer 106 formed on the dielectric layer 104 can be removed with a CMP process.

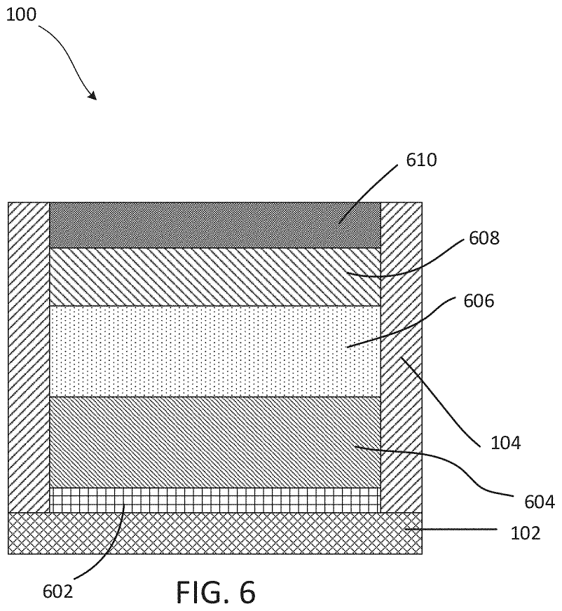

Referring now to FIG. 6, an example semiconductor device 100 is shown where the GaN layer includes several sub-layers. In this example, the layers include an AlN nucleation layer 602 formed on the substrate 102, a C-doped AlGaN buffer layer 604 formed on the nucleation layer 602, an intrinsic GaN channel layer 606 formed on the buffer layer 604, an intrinsic AlGaN cap layer 608 formed on the channel layer 606, and a p-GaN layer 610 formed on the cap layer 608. It should be appreciated that the GaN layer 106 (see, FIG. 5) may include or omit any number of sublayers, and the layers may be formed in a different order than the example shown in FIG. 6.

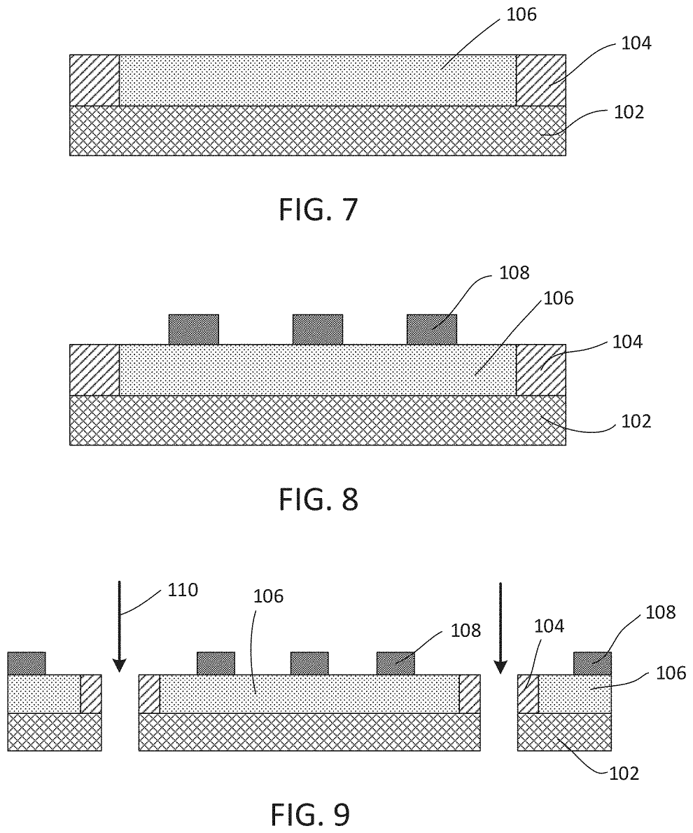

Referring now to FIG. 7, a CMP process is performed to remove any additional portions of the GaN layer 106 formed on the dielectric layer 104 (i.e., depicted as small triangles in FIG. 5), as discussed above with respect to FIG. 5. Optionally, a certain thickness of the dielectric layer 104 and the GaN layer 106 may also be removed during the CMP process. At this stage of the manufacturing process, the surface of the GaN layer 106 has been planarized and is ready for further processing.

Referring now to FIG. 8, after the planarization of the GaN layer 106, electronic devices 108 are formed thereon. In certain examples, the electronic devices are 200 V grade power devices for the 48 V DC-DC converter application. In other embodiments, the devices are power devices or radio frequency devices. In certain embodiments, the semiconductor device includes a source electrode, a gate electrode and a drain electrode. However, it should be appreciated that any suitable type of device may be formed.

Referring now to FIG. 9, after the electronic devices 108 have been formed, they are physically separated from each other by a scribing and breaking process 110. In certain embodiments, the electronic devices 108 are separated by sawing through the entire thickness of the dielectric layer 104 and the Si substrate 102. In other embodiments, the wafers are scribed in the regions corresponding to the dielectric layer 104, and then then physically broken apart along the scribe lines. Because the saw cut (or scribing) occurs in the area of the wafer corresponding the grid-like pattern of the dielectric layer, there is no wasted surface area (or a reduced amount of wasted surface area) of the wafer. In other words, even though the dielectric layer 104 reduces the total amount of the surface area of the wafer upon which the GaN layer 106 (and subsequently the electronic devices 108) can be formed, this does not impact the total number of devices that can be formed on a wafer because the dielectric layer 104 is formed in the wasted space (e.g., the kerf of the saw cut) between devices. In certain embodiments, the scribe lines may have a width ranging from about 25 μm to about 100 μm. In certain embodiments, the discrete areas of the GaN layer 106 (i.e., the windows in the grid-shaped pattern of the dielectric layer 104) have a width ranging from about 10 μm to about 1 mm, and have a length ranging from about 10 μm to about 1 mm. However, it should be appreciated that the width and length of these areas may be any suitable size. Thus, the GaN layer 106 formed in these smaller discrete areas between the sidewalls of the dielectric layer 104 can be grown with a reduction in dislocation defects and with a reduction of the problems associated with the lattice/thermal mismatch of the Si substrate 102 and the GaN layer 106 discussed above.

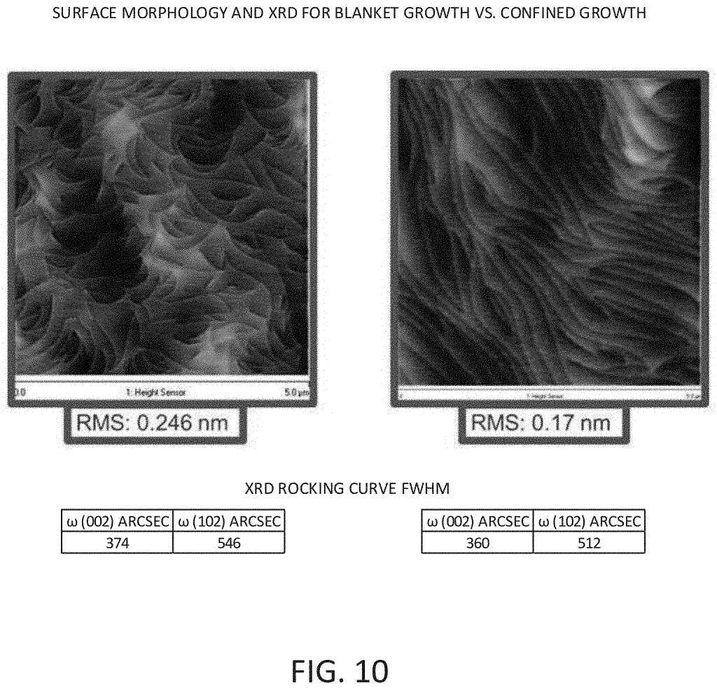

Referring now to FIG. 10, the image on the left is an enlarged view of a 5 μm area of the surface morphology of a GaN layer 106 that is formed by blanket growth of the GaN layer 106 (i.e., without the dielectric layer 104), and the image on the right is an enlarged view of a 5 μm area of the surface morphology of a GaN layer 106 that is formed by the confined growth of the GaN layer 106 (i.e., with the dielectric layer 104) according to the present embodiments. This example shows a different surface morphology for the confined growth method of the present embodiments, where there is a reduction in the root mean squared (RMS) surface roughness of the GaN layer 106 from 0.246 nm to 0.17 nm. It should be appreciated that FIG. 10 is merely one example, and it is used for comparison purposes to illustrate the differences in the surface morphology of the GaN layers when using confined growth versus blanket growth.

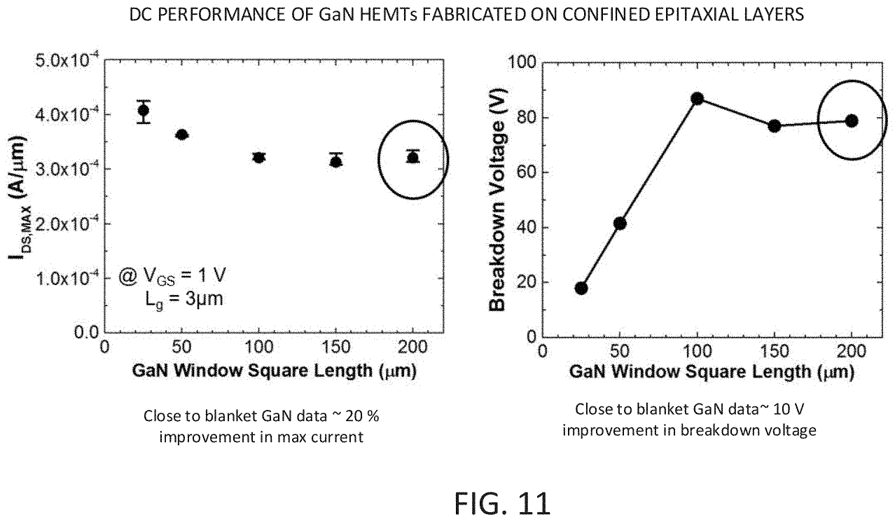

Referring now to FIG. 11, performance graphs for maximum current and breakdown voltage are shown for examples of GaN layers 106, where the dimensions of the discrete GaN growth area (i.e., the GaN window, or the spaces between the adjacent sidewalls of the dielectric layer 104) are varied from >0 μm to about 200 μm. In this example, the semiconductor device 100 is a high-electron-mobility transistor (HEMT), also known as heterostructure FET (HFET) or modulation-doped FET (MODFET). However, as indicated above, the type of semiconductor device may be any suitable device that a requires growth on a base GaN layer.

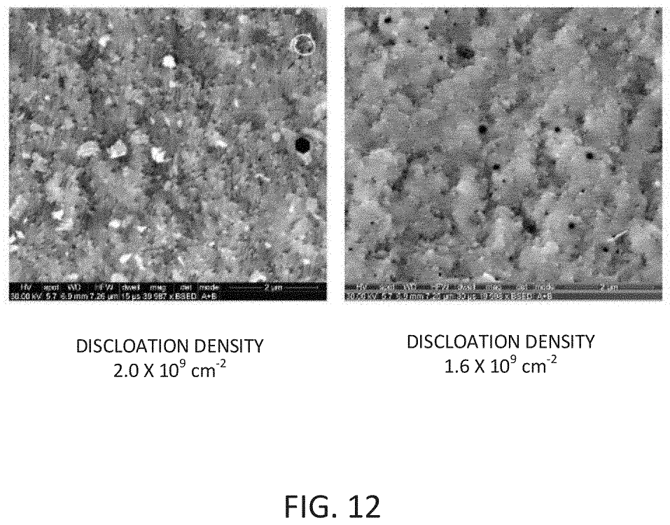

Referring now to FIG. 12, the image on the left is an enlarged view of an area of a GaN layer 106 that is formed by blanket growth of the GaN layer 106 (i.e., without the dielectric layer 104), and the image on the right is an enlarged view of a GaN layer 106 that is formed by the confined growth of the GaN layer 106 (i.e., with the dielectric layer 104) according to the present embodiments. This example shows a reduced dislocation defect density for the confined growth method of the present embodiments, where there is a reduction in the dislocation density of the GaN layer 106 from 2.0×10⁹ cm⁻² to 1.6×10⁹ cm⁻². It should be appreciated that FIG. 12 is merely one example, and it is used for comparison purposes to illustrate the differences in the dislocation densities of the GaN layers when using confined growth versus blanket growth.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming an electronic device, the method comprising:
forming a dielectric layer on a Si-based substrate;
etching away portions of the dielectric layer to form a crisscrossing grid pattern of remaining portions of the dielectric layer and to expose the substrate in areas where the dielectric layer is removed;
forming GaN-based layers on the substrate in growth areas between sidewalls of the remaining portions of the dielectric layer; and
forming a semiconductor device on the GaN-based layers.

2. The method according to claim 1, wherein the growth areas have a width ranging from 10 μm to 1 mm, and have a length ranging from 10 μm to 1 mm.

3. The method according to claim 1, wherein the remaining dielectric layer portions have a width ranging from about 1 μm to about 1 mm, have a length ranging from about 1 μm to about 1 mm, and have a height ranging from about 100 nm to about 10 μm.

4. The method according to claim 1,
wherein the GaN-based layers include a plurality of sublayers, each sublayer including at least one selected from the group consisting of Al, Ga, In and N, and
wherein forming the GaN-based layers includes:
forming an AlN nucleation layer on the substrate;
forming a C-doped AlGaN or InGaN buffer layer on the nucleation layer;
forming a GaN channel layer on the buffer layer; and
forming an AlGaN cap layer on the channel layer.

5. The method according to claim 1, wherein the method further comprises separating a plurality of the semiconductor devices from each other at locations corresponding to the dielectric layer.

6. The method according to claim 1, wherein the substrate has a <111> crystal structure.

7. The method according to claim 1, wherein the method further comprises, after forming the GaN layer, performing a CMP process to remove any GaN layer material formed on a top surface of the dielectric layer.

8. The method according to claim 1, wherein the dielectric layer comprises at least one material selected from the group consisting of PVD, ALD, PECVD, AlOx, TiOx, BN, SiN, SiBCN, SiO₂, and a ceramic material.

9. The method according to claim 1, wherein the semiconductor device includes a source electrode, a gate electrode and a drain electrode.

10. The method according to claim 1, wherein a width of remaining portions of the dielectric layer range from about 25 μm to about 100 μm, and a length of the remaining portions of the dielectric layer range from about 25 μm to about 100 μm.

11. An electronic device comprising:
a dielectric layer provided on a Si-based substrate, the dielectric layer having a crisscrossing grid pattern;
GaN-based layers provided on the substrate and in growth areas between sidewalls of the dielectric layer; and
a semiconductor device provided on the GaN-based layer.

12. The electronic device according to claim 11, wherein the growth areas have a width ranging from 10 μm to 1 mm, and have a length ranging from 10 μm to 1 mm.

13. The electronic device according to claim 11, wherein crisscrossing grid pattern portions of the dielectric layer have a width ranging from about 1 μm to about 1 mm, have a length ranging from about 1 μm to about 1 mm, and have a height ranging from about 100 nm to about 10 μm.

14. The electronic device according to claim 11, wherein the GaN-based layers include a plurality of sublayers, each sublayer including at least one selected from the group consisting of Al, Ga, In and N, and
wherein the GaN-based layers include:
an AlN nucleation layer formed on the substrate;
a C-doped AlGaN or InGaN buffer layer formed on the nucleation layer;
a GaN channel layer formed on the buffer layer; and
an AlGaN cap layer formed on the channel layer.

15. The electronic device according to claim 11, wherein the substrate has a <111> crystal structure.

16. The electronic device according to claim 11, wherein the dielectric layer comprises at least one material selected from the group consisting of PVD, ALD, PECVD, AlOx, TiOx, BN, SiN, SiBCN, SiO₂, and a ceramic material.

17. The electronic device according to claim 11, wherein the semiconductor device includes a source electrode, a gate electrode and a drain electrode.

18. The electronic device according to claim 11, wherein crisscrossing grid pattern portions of the dielectric layer have a width ranging from about 25 μm to about 100 μm, and a length ranging from about 25 μm to about 100 μm.

19. The electronic device according to claim 11, wherein the electronic device is a DC-DC converter.

20. The electronic device according to claim 11, wherein the GaN layer includes a GaN sublayer and an AlGaN sublayer.
